(19) United States
(12) Patent Application Publication
(10) Pub. No.: US 2010/0307682 A1
(43) Pub. Date: Dec. 9, 2010

(54) THERMALLY-ACTIVATED AND -HARDENABLE ADHESIVE FOIL, ESPECIALLY FOR ADHESION OF ELECTRONIC COMPONENTS AND FLEXIBLE PRINTED CIRCUIT PATHS

(75) Inventors: Uwe Schümann, Pinneberg (DE); Alexander Steen, Bonn (DE)

Correspondence Address: GERSTENZANG, WILLIAM C.;NORRIS MCLAUGHLIN & MARCUS, PA, 875 THIRD AVE, 8TH FLOOR, NEW YORK, NY, 10022, US

(73) Assignee: TESA SE, Hamburg (DE)

(21) Appl. No.: 12/864,693

(22) PCT Filed: Jan. 27, 2009
(86) PCT No.: PCT/EP2009/050866

§ 371 Date: Aug. 23, 2010

(30) Foreign Application Priority Data
Feb. 5, 2008 (DE) 10 2008 007 749.6

(51) Int. Cl. H05K 3/36; C08L 75/04; C08K 3/34

(52) U.S. Cl. 156/330; 525/452; 524/500; 524/447; 525/449

(57) ABSTRACT

Thermally-activated and hardenable adhesive foil for adhesion of electronic components and flexible printed circuit paths having an adhesive material composed of at least a) one chemically crosslinked or at least partially crosslinked polyurethane, b) one at least bifunctional epoxy resin, c) one hardener for the epoxy resin, in which the epoxy groups react chemically with the hardener at high temperatures, in which at least one of the starting materials of the polyurethane is a hydroxyl-functionalized polycarbonate and at least one of the starting materials of the polyurethane has a functionality greater than two

The invention relates to a thermally activatable and curable bonding sheet, to a method of producing it, and to the use thereof for adhesive bonding of electronic components, more particularly flexible printed circuits (FPCs) to give multilayer FPC circuits.

Flexible printed circuits find use in numerous electronic devices such as mobile radio telephones, digital cameras, computers, notebooks, printers, etc. They consist of an assembly of thin copper layers, which function as conductors, and thin polymeric layers, which serve as insulator layers. Polyimide is used predominantly as a polymeric layer, since it has a pronounced temperature resistance and chemical resistance and, moreover, possesses good insulator properties. For reasons of cost, polyethylene terephthalate (PET) is occasionally used as well.

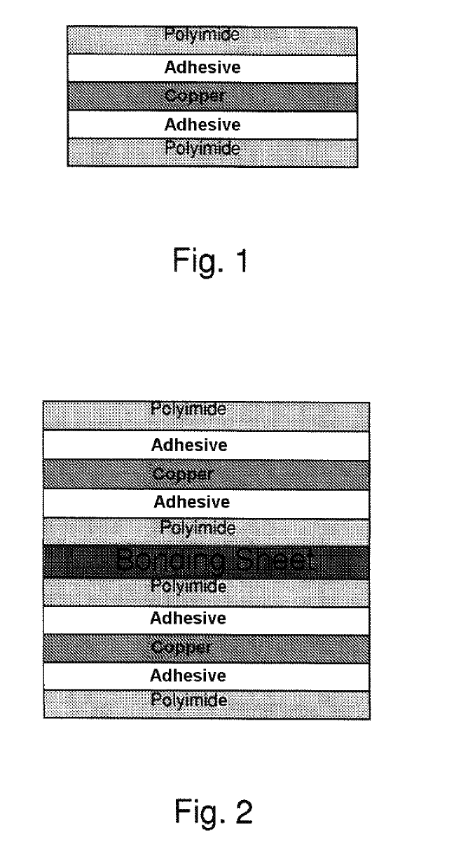

The polymeric layer may either be applied directly to the pretreated or unpretreated copper layer, or it may be applied to the copper layer by means of an adhesive. Furthermore, the polymeric layer may be applied to the copper layer either from one side only or from both sides. An FPC, therefore, may consist of different numbers of individual layers. In the case of polyimide layers adhered on both sides of the copper layer, the construction of the FPC is as shown in FIG. 1, for example.

Multilayer FPC circuits are produced when a plurality of these flexible printed circuits (FPCs) are bonded to one another flatly to give a larger assembly. Generally speaking, these adhesive bonds are made with bonding sheets, which are cured by heat, since the high bonding strengths needed for this application are generally achievable only with heat-curable adhesive systems. Bonding sheets for the hot adhesive bonding of FPCs to form multilayer circuits are also referred to as adhesive foils.

Where two FPCs are bonded to one another to form a two-layer circuit, the overall construction of the layers is as shown in FIG. 2, for example.

The bonding operation takes place at temperatures of 180° C., in some cases of up to 200° C. During this high temperature exposure, whose duration for some users may be up to one hour, with other users only 15 to 30 minutes, however, no volatile constituents must be released, since that would lead to formation of bubbles between the bonding sheet and the substrate. As well as the temperature exposure, the processing operation is also accompanied by high pressure loads, which may promote unwanted lateral oozing of the adhesive from the bondline. In order to counter this effect, the physical composition of the bonding sheet must be such that it still retains sufficiently high viscosity and sag resistance even under temperature exposure. In order to attain the required bonding strength, which in general is to be at least 15 N/cm in the T-peel test, and in order to counteract the effect of oozing from the bonding sheet, the bonding sheet ought to crosslink rapidly during the processing operation at the stated temperatures. Moreover, the bonds are required, after the hot-curing operation, to be solder bath-resistant. Solder bath-resistant means that the bond must be able to withstand a temperature load of 288° C. for approximately 10 seconds without formation of bubbles between the bonded substrates, without the adhesive emerging from the bondline in this time, and without any other instances of damage to the bond.

The use of a purely thermoplastic adhesive system therefore makes no sense for this application, since under the conditions referred to above it would ooze from the bonding sheet.

Compounds used for hot-curing adhesive formulations are mostly epoxy resins and phenolic resins. Heat-activatable adhesive tapes based on phenolic resole resin, of the kind described in DE 38 34 879 A1, for example, are normally excluded, since in the course of thermal curing they release volatile constituents, such as water, for example, and hence lead to formation of bubbles.

Using epoxy resins or phenolic resins alone to produce a heat-activatable bonding sheet in accordance with the stated profile of requirements is not possible, since such bonds, after curing, are relatively brittle, and hence have hardly any remaining flexibility. Accordingly, it is vital to integrate a flexibilizing component into the composition of the bonding sheet, which at the same time constitutes the scaffold of the sheet. The composition of a heat-curable sheet of this kind in principle would therefore consist of an elastomer component, forming the scaffold of the sheet and very largely determining the properties of the sheet in the unbonded state, and, integrated into the elastomer component, a heat-reactive component, which crosslinks under temperature and which ensures the high bonding strength after the hot-curing operation.

Examples of possible elasticizing components contemplated include thermoplastics, or thermoplastic elastomers, which are added to the adhesive.

JP 04 057 878 A, JP 04 057 879 A, JP 04 057 880 A, and JP 03 296 587 A disclose nitrile rubber and polyvinylbutyral as scaffold substances. DE 103 59 348 A1 uses acrylate copolymers as scaffold substance. DE 103 24 737 A1 discloses a bonding-sheet composition very generally comprising a thermoplastic, a resin, and an organically modified phyllosilicate and/or bentonite.

With these variants, however, there is the problem that they are not chemically crosslinked and may therefore ooze from the bondline under the prevailing temperature and pressure loads.

Another alternative is the use of elastomers which carry appropriate functional groups via which chemical crosslinking can take place between the resins employed and the scaffold polymer.

The disadvantage of all of the elastomers known for this use is that either they impart an unwanted inherent tack, or an unwanted tackiness toward polyimide, to the bonding sheet at room temperature, or else they undesirably lower the elasticity modulus of the bonding sheet or reduce its laminatability at 110° C. to 130° C.

Inherent tack or tackiness toward polyimide makes it more difficult to work with a bonding sheet in the adhesive bonding of FPCs to form multilayer FPCs, or even makes such bonding impossible, since, for the purpose of precise positioning, the bonding sheet must be able to be shifted back and forth on the FPCs to be bonded, and this is then no longer possible. This latter disadvantage affects, for example, thermally activatable and curable adhesive tapes, of the kind described in U.S. Pat. No. 5,478,885 A1, or epoxidized styrene-butadiene and/or styrene-isoprene based block copolymers. The epoxy system described in WO 96/33248 A1 has this disadvantage as well. Moreover, these adhesive tapes require long cure times for full curing.

A low elasticity of modulus on the part of the bonding sheet likewise makes it more difficult, or may even make it impossible, to work with the sheet.

With many applications in the area of the fabrication and processing of FPCs, the adhesive tapes are peeled from the release medium, which normally protects the adhesive tapes, and are then positioned on the substrates where bonding is to take place. In such operations it must be ensured that the adhesive tapes, which before this operation are often already diecut, are not deformed either during the removal of the release medium or during positioning. Since a certain force must be applied in order to peel them from the release medium, the adhesive tapes must have an elasticity modulus high enough to undergo this force without stretching or showing other types of deformation. An elasticity modulus of at least 50 N/mm² has proven suitable in practice. Heat-activatable adhesive tapes for FPC bonding that are based on nitrile rubber and polyvinylbutyral, as described in DE 10 2004 057 651 A1, or based on carboxylated nitrile rubber, as disclosed in DE 10 2004 057 650 A1, have emerged in practice to be too soft and also, in addition, to have inherent tack. The same disadvantages also affect the heat-activatable adhesive tapes that are described in DE 10 2004 031 189 A1 and DE 10 2004 031 188 A1 and comprise acid-modified or acid anhydride-modified vinylaromatic block copolymers.

Deficient laminatability of the bonding sheet at 110° C.-130° C. may likewise make it difficult or even impossible to work with the sheet. The object of laminating at the stated temperature is to fix the precisely positioned bonding sheet on the FPC with sufficient strength that from that moment on it can no longer be shifted back and forth without being removed entirely. The laminating process converts the adhesive sheet briefly into a tacky state which is sufficient for fixing.

Known elastomers which ensure the laminatability of the bonding sheet always have the disadvantage of giving the adhesive sheet too high an inherent tack or too low an elasticity modulus even at room temperature. Known elastomers with sufficiently low inherent tack at room temperature and an application-compatible, sufficiently high elasticity modulus result in bonding sheets which are not laminatable at 110° C.-130° C., especially not to polyimide.

Another property required of bonding sheets for the adhesive bonding of FPCs to give multilayer circuits is a very good electrical insulation. A volume resistivity of at least 10⁹ Ωm is a guideline value.

Furthermore, the thermally cured adhesive bond must not be moisture-sensitive. Testing takes place in general in the so-called potcooking test. For that test, the completed adhesive bond is stored at 120° C. and 100% relative humidity in a pressure cooker for 24 hours. There must be no reduction in bond strength.

Furthermore, the bonding sheet ought to be transportable and storable at room temperature, without gradually losing its adhesiveness, and without a decrease in bonding performance over time. Many of the bonding sheets currently on the market have to be transported and stored at low temperatures, which implies increased effort and complexity, associated with increased costs, and therefore constitutes a significant disadvantage.

It is an object of the invention to provide a dimensionally stable bonding sheet which is not tacky at room temperature and which allows flexible printed circuits (FPCs) to be bonded in a hot-curing operation to give multilayer circuits, and which does not display the above-outlined disadvantages of the prior art, or not to the same degree.

This object is achieved, surprisingly, by means of a thermally activatable and curable bonding sheet of the kind characterized in the main claim. The subclaims relate to advantageous developments of the bonding sheet, methods of producing it, and possibilities for use.

The invention accordingly provides a thermally activatable and curable bonding sheet consisting of an adhesive which is at least composed of

a) a chemically crosslinked or at least partly crosslinked polyurethane,
b) an at least difunctional epoxy resin,
c) a hardener for the epoxy resin, the epoxide groups reacting chemically with the hardener at high temperatures,
characterized in that
at least one of the starting materials of the polyurethane is a hydroxyl-functionalized polycarbonate and at least one of the starting materials of the polyurethane has a functionality of more than two.

According to one embodiment of the invention, one of the starting materials of the polyurethane may be a hydroxyl-functionalized polycarbonate having a functionality of more than two.

The ratio in weight fractions of a) to b)+c) is preferably in the range between 50:50 and 95:5. More preferably the ratio in weight fractions of a) to b)+c) is in the range between 70:30 and 90:10.

A particularly preferred bonding sheet of the invention is composed accordingly of 70% to 90% by weight of a chemically crosslinked or at least partly crosslinked polyurethane, at least one of the starting materials of the polyurethane being a hydroxyl-functionalized polycarbonate and at least one of the starting materials of the polyurethane having a functionality of more than two, and of 30% to 10% by weight of an at least difunctional epoxy resin, admixed with a hardener, the epoxide groups reacting chemically with the hardener at high temperatures.

Hydroxyl-functionalized polycarbonates have the general formula:

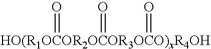

R₁, R₂, R₃, and R₄ are aliphatic hydrocarbon chains, but may also be or comprise aromatic hydrocarbon fragments, without departing from the concept of the invention. R₁, R₂, R₃, and R₄ may be identical, but may also differ partly or completely from one another. The structural element defining the polycarbonates is the —O—C(O)—O— moiety.

Hydroxyl-functionalized polycarbonates of the invention are available commercially, for example, under the product name Ravecarb from Caffaro (formerly: Enichem). The number-averaged average molecular weights of commercial hydroxyl-functionalized polycarbonates are in the range of 700-3300. Particularly preferred in accordance with the invention is the range of 1700-2000.

Further starting materials of the chemically crosslinked or at least partly crosslinked polyurethane are chain extenders, crosslinkers and/or polyisocyanates, more particularly di- and triisocyanates.

Chain extenders are low molecular mass, isocyanate-reactive, difunctional compounds. Low molecular mass means that the molecular weight of the chain extender is significantly smaller than the number-averaged average molecular weight of the hydroxyl-functionalized polycarbonate used. Examples of chain extenders are 1,2-ethanediol, 1,2-propanediol, 1,3-propanediol, 2-methyl-1,3-propanediol, 1,4-butanediol, 2,3-butanediol, propylene glycol, dipropylene glycol, 1,4-cyclohexanedimethanol, hydroquinone dihydroxyethyl ether, ethanolamine, N-phenyldiethanolamine, or m-phenylenediamine.

Crosslinkers are low molecular mass, isocyanate-reactive compounds compounds having a functionality of more than two. Low molecular mass means that the molecular weight of the crosslinker is significantly smaller than the number-averaged average molecular weight of the hydroxyl-functionalized polycarbonate used. Examples of crosslinkers are glycerol, trimethylolpropane, diethanolamine, triethanolamine and/or 1,2,4-butanetriol.

Polyisocyanates are all compounds which contain at least two isocyanate groups per molecule.

Polyisocyanates of the invention may be aliphatic and aromatic isocyanates. Examples contemplated include isophorone diisocyanate, hexamethylene diisocyanate, dicyclohexylmethane 4,4′-diisocyanate, tolylene diisocyanate, diphenylmethane 4,4′-diisocyanate or m-tetramethylxylene diisocyanate (TMXDI), mixtures of the stated isocyanates, or isocyanates derived chemically therefrom, examples being dimerized, trimerized or polymerized types, containing, for example, urea groups, uretdione groups or isocyanurate groups.

One example of a dimerized type is the HDI uretdione Desmodur N 3400® from Bayer. One example of a trimerized type is the HDI isocyanurate Desmodur N 3300®, likewise from Bayer.

Surprisingly, and also unforeseeable for the skilled worker, it has been found that not only good laminatability but also good development of adhesion and bond strength to the polyimide, and also, generally, to substrates, are made possible through thermal activation and curing if the polyurethane is in crosslinked or at least partly crosslinked form even prior to hot lamination and prior to hot curing. A polyurethane is in a crosslinked or at least partly crosslinked state when at least one starting material of the polyurethane has a functionality of more than two.

Accordingly, the chemically crosslinked or at least partly crosslinked polyurethane of the invention comprises at least either a crosslinker in accordance with the description above, or a polyisocyanate in accordance with the description above and having a functionality of more than two, or a combination of both.

The numerical fraction of the NCO-reactive groups of the crosslinker as a proportion of the total amount of NCO-reactive groups is preferably in the range between 30% and 90%. Particular preference is given to a fraction of 50% to 80%. Similarly, the fraction of NCO groups originating from a polyisocyanate having a functionality of more than two, as a proportion of the total amount of NCO groups in the starting materials of the chemically crosslinked or at least partly crosslinked polyurethane of the invention, is preferably in the range between 30% and 90%, more preferably in the range between 50% and 80%.

The ratio of the total number of isocyanate groups to the total number of isocyanate-reactive groups in the starting materials of the chemically crosslinked or at least partly crosslinked polyurethane of the invention is preferably 0.8 to 1.2. Particular preference is given to a ratio from 0.9 to 1.1. Accordingly, the invention does not intend the crosslinked or partly crosslinked polyurethane to retain a residual functionality, in the form of isocyanate-reactive groups or isocyanate groups that could be utilized for thermal activation and hot curing or for chemical attachment to the substrate.

The reaction of the isocyanates with the isocyanate-reactive groups, such as the hydroxyl or amino groups, for example, can be accelerated using all of the catalysts that are known to the skilled worker, such as, for example, tertiary amines, organobismuth or organotin compounds, to name but a few.

Epoxy resins are typically understood to encompass both monomeric and oligomeric compounds having more than one epoxide group per molecule. They may be reaction products of glycidol esters or epichlorohydrin with bisphenol A or bisphenol F or mixtures of these two. Likewise employable are epoxy novolak resins, obtained by reacting epichlorohydrin with the reaction product of phenols and formaldehyde. Monomeric compounds having two or more terminal epoxide groups, employed as diluents for epoxy resins, can also be used. Likewise employable are elastically modified epoxy resins.

Examples of some epoxy resins are Araldite™ 6010, CY-281™, ECN™ 1273, ECN™ 1280, MY 720, RD-2 from Ciba Gelgy, DER™ 331, 732, 736, DEN™ 432 from Dow Chemicals, EPON™ Resin 825, 826, 828, 830, 862, 1001F, 1002F, 1003F, 1004F, etc. from Hexion, and also Epikote™ 815, 816, 828, 834, 1001, 1002, 1004, 1007, 1009, etc., likewise from Hexion.

Commercial aliphatic epoxy resins are, for example, vinylcyclohexane dioxides such as ERL-4206, 4201, 4289 or 0400 from Union Carbide Corp.

Elasticized epoxy resins are available from Noveon under the Hycar name. Epoxide diluents, monomeric compounds having two or more epoxide groups, are, for example, Bakelite™ EPD, KR, EPD Z8, EPD HD, EDP WF, etc. from Bakelite AG or Polypox R9, R12, R15, R19, R20, etc. from UCCP.

The adhesive tape may comprise more than one epoxy resin, in which case preferably two epoxy resins are used. One particularly preferred embodiment uses one solid and one liquid epoxy resin. The ratio in weight fractions of solid to liquid epoxy resin is preferably in the 0.5:1 to 4:1 range and, in one particularly preferred embodiment, in the 1:1 to 3:1 range.

Hot curing in the context of the present invention takes place via crosslinking of the epoxy resins with a thermally activatable hardener. Possible epoxy resin hardeners contemplated include all of the compounds that are known for this purpose, such as, for instance, dicyandiamide, dicyandiamide in combination with accelerants such as, for example, compounds containing urea groups or imidazole derivatives, anhydrides such as, for example, phthalic anhydride or substituted phthalic anhydrides, polyamides, polyamidoamines, polyamines, melamine-formaldehyde resins, urea-formaldehyde resins, phenol-formaldehyde resins, polyphenols, polysulfides, ketimines, novolaks, carboxyl-group-functionalized polyesters or blocked isocyanates, and also combinations of the compounds stated.

It is additionally possible to add rheological additives to the adhesive of the invention, said additives producing a pseudoplastic flow behavior of the starting materials of the polyurethane, which are dissolved in a solvent, in the unreacted state, and also of the other dissolved starting materials of the adhesive. This effect is desired in order to be able to coat the starting materials of the adhesive flawlessly on an antiadhesive carrier sheet, before the starting materials react to form the polyurethane during the evaporation or after the evaporation of the solvent.

In order to bring about a suitable pseudoplastic flow behavior of the dissolved starting materials of the adhesive, all rheological additives known to the skilled worker can be contemplated. Examples of rheological additives are fumed silicas, phyllosilicates (bentonites), high molecular mass polyamide powders or castor oil derivative powders. One preferred embodiment uses hydrophobized fumed silica, and one particularly preferred embodiment uses a hydrophobized fumed silica finely predispersed in a solvent.

In one possible embodiment the adhesive comprises further formulating constituents such as, for example, fillers, aging inhibitors (antioxidants), light stabilizers, UV absorbers, and also other auxiliaries and additives.

Fillers contemplated include all known fillers, such as chalk, talc, barium sulfate, silicates, color pigments or carbon black, for example.

The use of antioxidants, light stabilizers, and UV absorbers is advantageous but not mandatory.

The appropriate antioxidants, light stabilizers, and UV absorbers include, for example, sterically hindered amines, sterically hindered phenols, triazine derivatives, benzotriazoles, hydroquinone derivatives, amines, organic sulfur compounds or organic phosphorus compounds, and combinations of these compounds.

Light stabilizers used are, additionally, those disclosed in Gaechter and Müller, Taschenbuch der Kunststoff-Additive, Munich 1979, in Kirk-Othmer (3rd) 23, 615 to 627, in Encycl. Polym. Sci. Technol. 14, 125 to 148, and in Ullmann (4th) 8, 21; 15, 529, 676.

The thermally activatable and curable bonding sheet of the invention is produced preferably by dissolving or finely dispersing those of the polyurethane starting materials whose functionality is not greater than two, and therefore do not contribute to crosslinking, together with the epoxy resin or resins, the hardener for the epoxy resin, and the other compounds, in a solvent, preferably in butanone. Shortly prior to coating, those starting materials of the polyurethane whose functionality is more than two are mixed in, and the now reactive mixture is coated onto an antiadhesive medium, such as an antiadhesive sheet or an antiadhesively treated paper, for example, which is preferably passed through a drying tunnel whose temperature setting is selected as a function of the solvent used, the tunnel length, the catalyst, the catalyst concentration, and the precise composition of the polyurethane. As a general rule, an average temperature of 80° C. to 120° C. is appropriate. In the course of passage through the drying tunnel, the solvent evaporates, and the crosslinked or at least partly crosslinked polyurethane is produced by chemical reaction, and, after passage through the drying tunnel, can be wound up on the antiadhesive medium, in the form of a solid bonding sheet of the invention. The thickness of the bonding sheet of the invention is preferably 15 to 50 μm, more preferably 20 to 30 μm. The epoxy resins and the hardener for the epoxy resins participate only to a very small extent, or not at all, in the reaction during passage through the drying tunnel. They are available as additionally reactive constituents of the bonding sheet for the curing at 180° to 200° C.

The thermally activatable and curable bonding sheet of the invention exhibits outstanding product properties which as such were unforeseeable even for the skilled worker. The bonding sheet of the invention is not tacky at room temperature. It can be shifted easily back and forth on the substrates where bonding is to take place, more particularly on FPCs, without sticking to them. It is sufficiently solid and is sufficiently dimensionally stable even at a thickness of only 20 to 30 μm. Accordingly, even after the diecutting operation, it can be peeled from the antiadhesive medium and placed onto the substrate where bonding is to take place, without disruptive deformations. Despite the crosslinking or at least partial crosslinking of the polyurethane, the bonding sheet of the invention can be laminated at 110° to 130° C. It is suitable for the adhesive bonding of flexible printed circuits (FPCs) to give multilayer circuits in a hot-curing operation at 180° C. to 200° C. under pressure of approximately 15 bar. In the course of this procedure there is chemical crosslinking of the epoxy resins, and at the same time a very firm bond is built up between the substrates to be bonded, more particularly polyimide, and this bond is durable, sufficiently flexible, and insensitive to moisture. The bond to the polyimide is generally so solid that any attempt to part it results in separation of the polyimide from the copper. In the course of the hot-curing operation, there are no instances of oozing of the sheet from the bondline. Moreover, the bonding sheet is solder bath-resistant and features very good electrical insulation.

The bonding sheet of the invention can be transported and stored at room temperature without decline in the bonding performances over time.

The bonding sheet can be laminated by brief temperature exposure at from 110° C. to 130° C. At processing temperatures in the range from 180° C. to 200° C. and an applied pressure of approximately 15 bar, the bonding sheet develops, and durably ensures, a chemically crosslinked bond, which at the same time is solid, between the substrates to be bonded, especially polyimide. It does not ooze from the bondline. Moreover, the bonding sheet is solder bath-resistant and, after thermal curing, is resistant to moisture. It features very good electrical insulation.

The aim of the text below is to illustrate the invention in detail, using working examples, without wishing thereby to restrict the invention unnecessarily.

### WORKING EXAMPLES

The coating operations in the examples took place on a customary laboratory coating unit for continuous coating. The web width was 50 cm. The width of the coating slot was set such that the thickness of the sheet produced was always 25 μm. The length of the heating tunnel was approximately 12 m. The temperature in the heating tunnel was divisable into four zones. The first zone was set at 100° C., the further zones at 110° C.

The individual compounds required for preparing the adhesive on which the bonding sheet is based were mixed in a customary heatable and evacuatable mixing vessel.

Table 1 lists the base materials used for preparing the adhesives which are subsequently coated out to form the bonding sheet of the invention, in each case with their trade name and manufacturer. The raw materials specified are all freely available commercially.

TABLE 1
List of raw materials used for preparing the adhesives as per the subsequent examples

| Trade name | Chemical basis | Manufacturer/Supplier |
|---|---|---|
| Ravecarb 107 ® | Polycarbonate diol, number-averaged | Caffaro |
| | average molecular weight: 1760-1950 | |
| | OH number: 1080 mmol OH/kg | |
| MP-Diol ® | Methylpropanediol, OH number: 22222 mmol | Lyondell |
| | OH/kg | |
| Addolink TR ® | Trimethylolpropane, OH number: 22014 mmol | Rhein Chemie |
| | OH/kg | |
| Glycerol | 1,2,3-propanetriol, OH number: 32573 mmol | Merck |
| | OH/kg | |
| Epikote 828 ® | Liquid epoxy resin based on bisphenol A | Hexion |
| Epikote 1001 ® | Solid epoxy resin based on bisphenol A | Hexion |
| Dyhard 100S ® | Dicyandiamide | Evonik |
| Coscat 83 ® | Organobismuth compound | C.H. Erbsloh |
| VP DISP MEK | 15% dispersion of Aerosil R202 in butanone | Evonik |
| 5015X ® | | |
| Vestanat IPDI ® | Isophorone diisocyanate, NCO number: | Evonik |
| | 8998 mmol NCO/kg | |
| Desmodur N | Trimerized hexamethylene diisocyanate, | Bayer |
| 3300 ® | NCO number: 5143 mmol NCO/kg | |

A further operational auxiliary used is commercially available butanone.

Set out in the text below are four formulas for preparing the adhesive of the invention that is coated out to give the bonding sheet of the invention, the formulas being given in each case in the form of a table. For greater ease of clarity, the formulas are each based on a 100 kg batch. The solvent is not included in the 100 kg calculation, since it evaporates following passage through the heating tunnel and is therefore not a constituent of the bonding sheet. It is merely an operational auxiliary.

### Example 1

| | | |
|---|---|---|
| Ravecarb 107 | 43.9 | kg (47.4 mol OH) |
| MP-Diol | 2.4 | kg (53.5 mol OH) |
| Addolink TR | 6.2 | kg (136.5 mol OH) |
| Vestanat IPDI | 26.4 | kg (237.5 mol NCO) |
| Epikote 828 | 5.0 | kg |
| Epikote 1001 | 10.0 | kg |
| Dyhard 100S | 1.0 | kg |
| Coscat 83 | 0.1 | kg |
| Aerosil R202* | 5.0 | kg |
| Total | 100.0 | kg |

*Aerosil R202 is added in the form of the 15% dispersion VP DISP MEK 5015X. 5.0 kg of Aerosil R202 correspond to 33.34 kg of the dispersion VP DISP MEK 5015X.

In order to set an optimally coatable viscosity, 32 kg of butanone are also added to the mixture.

The production process is as follows:

In a heatable and evacuatable mixer from Molteni, Ravecarb 107, MP-Diol, Epikote 828, Epikote 1001, Dyhard 100S and Coscat 83 are mixed for an hour and a half under reduced pressure with a set temperature of 40° C. The mixture is subsequently cooled to room temperature with stirring under an applied vacuum. When room temperature is reached, the vacuum is broken with air and the dispersion VP DISP MEK and also the additional butanone are added, followed by mixing for 10 minutes. After that, the isocyanate is added, and is mixed in for 40 minutes. The NCO-terminated prepolymer prepared in this way is stored under cover and, after one day of storage, is blended with Addolink TR. After a stirred-incorporation phase of approximately one hour, the mixture is coated onto a siliconized PET film with a thickness of 50 μm, the slot adjustment being selected such that drying produces a 25 μm thick film. Subsequent drying takes place in a heating tunnel at 100° to 110° C. as indicated above.

The adhesional properties are investigated using the test methods described.

### Example 2

| | | |
|---|---|---|
| Ravecarb 107 | 43.9 | kg (47.4 mol OH) |
| MP-Diol | 1.6 | kg (35.6 mol OH) |
| Addolink TR | 7.0 | kg (154.1 mol OH) |
| Vestanat IPDI | 26.4 | kg (237.5 mol NCO) |
| Epikote 828 | 5.0 | kg |
| Epikote 1001 | 10.0 | kg |
| Dyhard 100S | 1.0 | kg |
| Coscat 83 | 0.1 | kg |
| Aerosil R202* | 5.0 | kg |
| Total | 100.0 | kg |

*Aerosil R202 is added again in the form of the 15% dispersion VP DISP MEK 5015X. 5.0 kg of Aerosil R202 correspond to 33.34 kg of the dispersion VP DISP MEK 5015X.

In order to set an optimally coatable viscosity, 32 kg of butanone are also added to the mixture.

The production process is as follows:

In a heatable and evacuatable mixer from Molteni, Ravecarb 107, MP-Diol, Epikote 828, Epikote 1001, Dyhard 100S and Coscat 83 are mixed for an hour and a half under reduced pressure with a set temperature of 40° C. The mixture is subsequently cooled to room temperature with stirring under an applied vacuum. When room temperature is reached, the vacuum is broken with air and the dispersion VP DISP MEK and also the additional butanone are added, followed by mixing for 10 minutes. After that, the isocyanate is added, and is mixed in for 40 minutes. The NCO-terminated prepolymer prepared in this way is stored under cover and, after one day of storage, is blended with Addolink TR. After a stirred-incorporation phase of approximately one hour, the mixture is coated onto a siliconized PET film with a thickness of 50 μm, the slot adjustment being selected such that drying produces a 25 μm thick film. Subsequent drying takes place in a heating tunnel at 100° to 110° C. as indicated above.

The adhesional properties are investigated using the test methods described.

### Example 3

| | | |
|---|---|---|
| Ravecarb 107 | 49.9 | kg (53.9 mol OH) |
| Glycerol | 5.0 | kg (162.9 mol OH) |
| Vestanat IPDI | 24.0 | kg (216.0 mol NCO) |
| Epikote 828 | 5.0 | kg |
| Epikote 1001 | 10.0 | kg |
| Dyhard 100S | 1.0 | kg |
| Coscat 83 | 0.1 | kg |
| Aerosil R202* | 5.0 | kg |
| Total | 100.0 | kg |

*Aerosil R202 is added again in the form of the 15% dispersion VP DISP MEK 5015X. 5.0 kg of Aerosil R202 correspond to 33.34 kg of the dispersion VP DISP MEK 5015X.

In order to set an optimally coatable viscosity, 32 kg of butanone are also added to the mixture.

The production process is as follows:

In a heatable and evacuatable mixer from Molteni, Ravecarb 107, Epikote 828, Epikote 1001, Dyhard 100S and Coscat 83 are mixed for an hour and a half under reduced pressure with a set temperature of 40° C. The mixture is subsequently cooled to room temperature with stirring under an applied vacuum. When room temperature is reached, the vacuum is broken with air and the dispersion VP DISP MEK and also the additional butanone are added, followed by mixing for 10 minutes. After that, the isocyanate is added, and is mixed in for 40 minutes. The NCO-terminated prepolymer prepared in this way is stored under cover and, after one day of storage, is blended with glycerol. After a stirred-incorporation phase of approximately one hour, the mixture is coated onto a siliconized PET film with a thickness of 50 μm, the slot adjustment being selected such that drying produces a 25 μm thick film. Subsequent drying takes place in a heating tunnel at 100° to 110° C. as indicated above.

The adhesional properties are investigated using the test methods described.

### Example 4

| | | |
|---|---|---|
| Ravecarb 107 | 49.2 | kg (53.1 mol OH) |
| MP-Diol | 4.8 | kg (106.7 mol OH) |
| Vestanat IPDI | 7.8 | kg (70.2 mol NCO) |
| Desmodur N 3300 | 17.1 | kg (87.9 mol NCO) |
| Epikote 828 | 5.0 | kg |
| Epikote 1001 | 10.0 | kg |
| Dyhard 100S | 1.0 | kg |
| Coscat 83 | 0.1 | kg |
| Aerosil R202* | 5.0 | kg |
| Total | 100.0 | kg |

*Aerosil R202 is added again in the form of the 15% dispersion VP DISP MEK 5015X. 5.0 kg of Aerosil R202 correspond to 33.34 kg of the dispersion VP DISP MEK 5015X.

In order to set an optimally coatable viscosity, 32 kg of butanone are also added to the mixture.

The production process is as follows:

In a heatable and evacuatable mixer from Molteni, Ravecarb 107, MP-Diol, Epikote 828, Epikote 1001, Dyhard 100S and Coscat 83 are mixed for an hour and a half under reduced pressure with a set temperature of 40° C. The mixture is subsequently cooled to room temperature with stirring under an applied vacuum. When room temperature is reached, the vacuum is broken with air and the dispersion VP DISP MEK and also the additional butanone are added, followed by mixing for 10 minutes. After that, the Vestanat IPDI is added, and is mixed in for 40 minutes. The OH-terminated prepolymer prepared in this way is stored under cover and, after one day of storage, is blended with Desmodur N 3300. After a stirred-incorporation phase of approximately one hour, the mixture is coated onto a siliconized PET film with a thickness of 50 μm, the slot adjustment being selected such that drying produces a 25 μm thick film. Subsequent drying takes place in a heating tunnel at 100° to 110° C. as indicated above.

The adhesional properties are investigated using the test methods described.

### Comparative Example

| | | |
|---|---|---|
| Ravecarb 107 | 60.2 | kg (65.0 mol OH) |
| MP-Diol | 3.3 | kg (73.3 mol OH) |
| Vestanat IPDI | 15.4 | kg (138.6 mol NCO) |
| Epikote 828 | 5.0 | kg |
| Epikote 1001 | 10.0 | kg |
| Dyhard 100S | 1.0 | kg |
| Coscat 83 | 0.1 | kg |
| Aerosil R202* | 5.0 | kg |
| Total | 100.0 | kg |

*Aerosil R202 is added again in the form of the 15% dispersion VP DISP MEK 5015X. 5.0 kg of Aerosil R202 correspond to 33.34 kg of the dispersion VP DISP MEK 5015X.

In order to set an optimally coatable viscosity, 32 kg of butanone are also added to the mixture.

The production process is as follows:

In a heatable and evacuatable mixer from Molteni, Ravecarb 107, MP-Diol, Epikote 828, Epikote 1001, Dyhard 100S and Coscat 83 are mixed for an hour and a half under reduced pressure with a set temperature of 40° C. The mixture is subsequently cooled to room temperature with stirring under an applied vacuum. When room temperature is reached, the vacuum is broken with air and the dispersion VP DISP MEK and also the additional butanone are added, followed by mixing for 10 minutes. This is followed by the addition of the isocyanate. After a stirred-incorporation phase of approximately one hour, the mixture is coated onto a siliconized PET film with a thickness of 50 μm, the slot adjustment being selected such that drying produces a 25 μm thick film. Subsequent drying takes place in a heating tunnel at 100° to 110° C. as indicated above.

The adhesional properties are investigated using the test methods described.

### Test Methods

In order to test the adhesional properties of the bonding sheets produced according to examples 1-4 and according to the comparative example, two flexible circuits consisting of a copper-polyimide assembly are bonded by means of the bonding sheets. To accomplish this, the bonding sheet is laminated between two copper-polyimide sheets, using a hot-roll laminator, at a temperature of 100-120° C., by the polyimide side. After the laminating operation, the adhesive-bonding operation proper takes place in a vacuum hot press from Lauffer at 180° C. for 30 minutes under a pressure of 15 bar.

### 1) Bonding Strength in the T-Peel Test (IPC TM 650 2.4.9)

The bonding strengths of the heat-curable sheets were determined after polyimide-side adhesive bonding of two copper-polyimide laminates in accordance with the IPC standard in a 180° peel test.

### 2) Solder Bath Test

In order to determine the thermal and thermal-shock resistance of the assemblies produced using the heat-curable sheets, test specimens measuring 1.5×12.5 cm are subjected to a soldering metal float test. The test specimens in this test are placed by one side for 10 seconds onto a bath of melted solder at a set temperature of 288° C. After the test, the test specimens are assessed visually for formation of bubbles. A pass is scored in the test if there is no apparent formation of bubbles.

### 3) Moisture Storage

For determining the moisture resistance of the adhesive bonds, the 1.5×12.5 cm test specimens are subjected to what is called the PCT test. In this test, the test specimens are stored for 24 hours under a pressure of 2 bar in steam at a temperature of 120° C. After this, the bonding strength is measured by the T-peel test.

### 4) Volume Resistivity (IPC TM 650 2.5.17)

In order to ensure faultless functioning of the electronic circuits, there must be no short circuits between the individual layers within the multilayer construction. Accordingly, the adhesive must have a sufficiently high insulating effect. The electrical resistance is determined by determination of the volume resistivity of the bonding sheet. The sheet is placed between two gold electrodes one above the other, which are additionally loaded with a weight in order to ensure optimum contact. At an applied voltage of 500 V, the resistance is measured and is converted, using the measured thickness of the bonding sheet, into the volume resistivity, with the unit [Ωm].

### 5) Elasticity Modulus

The elasticity modulus was determined in accordance with ISO 527-1 using the standard 5A test specimens defined in DIN EN ISO 527-2. The tensile speed was 300 mm/min.

### Results:

The results of the tests conducted are given in the tables below:

| | | | | | Comparative |
|---|---|---|---|---|---|
| | Example 1 | Example 2 | Example 3 | Example 4 | example |
| T-peel test (N/cm) | 21.4 | 20.1 | 18.7 | 16.3 | |
| Solder bath test | Pass | Pass | Pass | Pass | No solder bath |
| | | | | | resistance; |
| | | | | | adhesive runs |
| | | | | | from the bondline |
| Moisture storage | 19.3 | 19.1 | 18.4 | 17.8 | |
| T-peel test after PCT | | | | | |
| test | | | | | |
| Volume resistivity [Ωm] | 2.33*10\hat{ }12 | 1.74*10\hat{ }12 | 2.28*10\hat{ }12 | 0.64*10\hat{ }12 | |
| Inherent tack | No inherent | No inherent | No inherent | No inherent | |
| | tack | tack | tack | tack | |
| Laminatability at | Can be | Can be | Can be | Can be | |
| 110° C. | laminated | laminated | laminated | laminated | |
| Oozing at | No oozing | No oozing | No oozing | No oozing | Bonding sheet |
| 180° C./15 bar/30 min | | | | | exhibits severe |
| | | | | | oozing |
| Storage stability half | Storage- | Storage- | Storage- | Storage- | |
| year at room temperature | stable | stable | stable | stable | |

1. A thermally activatable and curable bonding sheet for the adhesive bonding of electronic components and flexible printed circuits, having an adhesive comprised of
a) a chemically crosslinked or at least partly crosslinked polyurethane,
b) an at least difunctional epoxy resin,
c) a hardener for the epoxy resin, the epoxide groups reacting chemically with the hardener when heated,
wherein
at least one of the starting materials of the polyurethane is a hydroxyl-functionalized polycarbonate and at least one of the starting materials of the polyurethane has a functionality of more than two.

2. The bonding sheet of claim 1,
wherein
the weight ratio of a) to b)+c) is in the range between 50:50 and 95:5.

3. The bonding sheet of claim 1
wherein
chain extenders, crosslinkers and/or polyisocyanates, are used as starting materials for the chemically crosslinked or at least partly crosslinked polyurethane.

4. The bonding sheet of claim 1, wherein
the ratio of the total number of isocyanate groups to the total number of isocyanate-reactive groups in the starting materials of the chemically crosslinked or at least partly crosslinked polyurethane is 0.8 to 1.2.

5. The bonding sheet of claim 3, wherein
low molecular mass, isocyanate-reactive compounds having a functionality of more than two, are used as crosslinkers.

6. The bonding sheet of claim 5, wherein
the numerical fraction of the NCO-reactive groups in the crosslinker or crosslinkers as a proportion of the total amount of NCO-reactive groups is in the range between 30% and 90%.

7. The bonding sheet of claim 3, wherein the polyisocyanate is selected from the group consisting of isophorone diisocyanate, hexamethylene diisocyanate, dicyclohexylmethane 4,4′-diisocyanate, tolylene diisocyanate, diphenylmethane 4,4′-diisocyanate, m-tetramethylxylene diisocyanate (TMXDI), mixtures of said isocyanates, and isocyanates derived chemically therefrom.

8. The bonding sheet of claim 3, wherein
the numerical fraction of NCO groups of the polyisocyanate having a functionality of more than 2 as a proportion of the total amount of NCO groups is in the range between 30% and 90%.

9. The bonding sheet of claim 1, wherein
more than one epoxy resin is present.

10. The bonding sheet of claim 1, wherein the epoxy resins are crosslinked with a thermally activatable hardener.

11. The bonding sheet of claim 1,
further comprising
rheological additives selected from the group consisting of fumed silicas, phyllosilicates (bentonites), high molecular mass polyamide powders and castor oil derivative powders.

12. The bonding sheet claim 1,
further comprising formulating constituents selected form the group consisting of fillers, aging inhibitors (antioxidants), light stabilizers and UV absorbers.

13. A method for adhesive bonding of electronic components and/or flexible printed circuits (FPCs) which comprises bonding same with the bonding sheet of claim 1.

14. The method of claim 13, wherein said electronic components and/or flexible printed circuits are bonded on polyimide.

15. The bonding sheet of claim 2, wherein said weight ratio is between 70:30 and 90:10.

16. The bonding sheet of claim 4, wherein said ratio is 0.9 to 1.1.

17. The bonding sheet of claim 5, wherein said crosslinkers are selected from the group consisting of trimethylolpropane, diethanolamine, triethanolamine and 1,2,4-butanetriol.

18. The bonding sheet of claim 9, wherein one solid and one liquid epoxy resin are present, the weight ratio of solid to liquid epoxy resin being in the range from 0.5:1 to 4:1.

19. The bonding sheet of claim 10, where said thermally activatable hardener is selected from the group consisting of dicyandiamide, dicyandiamide in combination with accelerants, anhydrides, polyamides, polyamidoamines, polyamines, melamine-formaldehyde resins, urea-formaldehyde resins, phenol-formaldehyde resins, polyphenols, polysulfides, ketimines, novolaks, carboxyl-group-functionalized polyesters, blocked isocyanates, and combinations thereof.
